(19) United States
(12) Patent Application Publication
(10) Pub. No.: US 2010/0263705 A1
(43) Pub. Date: Oct. 21, 2010

(54) SOLAR CELL, SOLAR CELL MODULE, AND THE METHOD OF MANUFACTURING THE SOLAR CELL

(75) Inventors: Daisuke Ide, Kobe City (JP); Hitoshi Sakata, Kobe City (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD, Moriguchi City (JP)

(21) Appl. No.: 12/731,276

(22) Filed: Mar. 25, 2010

(30) Foreign Application Priority Data
Apr. 20, 2009 (JP) 2009-102329

(51) Int. Cl. H01L 31/042; H01L 31/00; H01L 31/18

(52) U.S. Cl. 136/244; 136/255; 438/57; 257/E31.052

(57) ABSTRACT

An aspect of the invention provides a solar cell that comprises: a semiconductor substrate including a light-receiving surface and a back surface that is disposed at the opposite side from the light-receiving surface; a first conductivity type semiconductor region having a first conductivity type and formed on the back surface, the first conductivity type semiconductor region is a region that a first dopant is doped into the semiconductor substrate by laser radiation, wherein the first conductivity type semiconductor region is a region formed to extend in a direction that intersects cleavage planes of the semiconductor substrate; and a second conductivity type semiconductor region having a second conductivity type that is different from the first conductivity type and formed on the back surface.

This application claims the benefit of priority under 35 U.S.0 §119 to the prior Japanese Patent Application No. P2009-102329 entitled “SOLAR CELL” filed on Apr. 20, 2009, the entire contents of which are incorporated herein by reference.

### BACKGROUND OF THE INVENTION

1. Field of the Invention

The invention relates to a back junction solar cell.

2. Description of Related Art

Solar cells can convert sunlight energy, which is clean and unlimited, directly into electric energy. Therefore, solar cells are expected as a new energy source.

A so-called back junction solar cell is a solar cell including an n-type semiconductor layer and a p-type semiconductor layer both of which are formed on the back surface of a semiconductor substrate (see, for example, JP-A 2004-221149).

One of the disclosed methods of manufacturing such solar cells is to introduce dopants into a semiconductor substrate by radiating with laser light onto a dopant layer coated on the semiconductor substrate (see Akiyoshi OGANE, “Application of Laser Doping Technique to Bulk and Thin Film Multicrystalline Silicon Solar Cells,” The Murata Science Foundation Annual Report, No. 22, 2008, pp. 662-664). According to this method, microscopic patterns of an n-type semiconductor layer and a p-type semiconductor layer can be easily formed without relying on such methods as photolithography.

However, portion of the semiconductor substrate radiated with laser light is subjected to a sharp temperature increase upon the start of the laser radiation, and then to a sharp temperature decrease upon the completion of the laser radiation. Such temperature changes may cause a strain within the semiconductor substrate thereby causing formation of cracks in the semiconductor substrate.

### SUMMARY OF THE INVENTION

An aspect of the invention provides a solar cell that comprises: a semiconductor substrate including a light-receiving surface and a back surface that is disposed at the opposite side from the light-receiving surface; a first conductivity type semiconductor region having a first conductivity type and formed on the back surface, the first conductivity type semiconductor region is a region that a first dopant is doped into the semiconductor substrate by laser radiation, wherein the first conductivity type semiconductor region is a region formed to extend in a direction that intersects cleavage planes of the semiconductor substrate; and a second conductivity type semiconductor region having a second conductivity type that is different from the first conductivity type and formed on the back surface.

The term “conductivity type” refers to the majority semiconductor charge carrier, negative electrons for n-type or positive holes for p-type.

Another aspect of the invention provides a method of manufacturing a solar cell, which comprises steps of: forming, on a semiconductor substrate including a light-receiving surface and a back surface that is disposed at the opposite side from the light-receiving surface, a first conductivity type semiconductor region on the back surface and having a first conductivity type; and forming a second conductivity type semiconductor region on the back surface and having a second conductivity type that is different from the first conductivity type, wherein the first conductivity type semiconductor region is formed by doping a first dopant into the semiconductor substrate by laser radiation directed in a direction that intersects a cleavage plane of the semiconductor substrate.

Still another aspect of the invention provides a solar cell module that comprises: a plurality of solar cells, the solar cells comprising solar cell comprising: a semiconductor substrate including a light-receiving surface and a back surface that is disposed at the opposite side from the light-receiving surface; a first conductivity type semiconductor region having a first conductivity type and formed on the back surface, the first conductivity type semiconductor region is a region that a first dopant is doped into the semiconductor substrate by laser radiation, wherein the first conductivity type semiconductor region is a region formed to extend in a direction that intersects cleavage planes of the semiconductor substrate; and a second conductivity type semiconductor region having a second conductivity type that is different from the first conductivity type and formed on the back surface; a wiring material that electrically connects each of the plurality of solar cells; a light-receiving-surface-side protection material disposed on a light-receiving-surface side of each solar cell; a back-surface-side protection material disposed on a back-surface side of each solar cell; and a sealing material that seals the solar cell and the wiring material and disposed between the light-receiving-surface-side protection material and back-surface-side protection material.

### BRIEF DESCRIPTION OF THE DRAWINGS

FIG. 1 is a side view illustrating solar cell module 100 according to a first embodiment.

FIG. 2 is a plan view illustrating solar cell 10 according to the first embodiment and seen from a back-surface side.

FIG. 3 is an enlarged sectional view taken along an A-A line of FIG. 2.

FIG. 4 is an enlarged plan view illustrating solar cell string 1 according to the first embodiment and seen from the back-surface side.

FIGS. 5A and 5B are diagrams explaining a method of manufacturing solar cell module 100 according to the first embodiment.

FIGS. 6A and 6B are diagrams explaining a method of manufacturing solar cell module 100 according to the first embodiment.

FIGS. 7A and 7B are diagrams explaining a method of manufacturing solar cell module 100 according to the first embodiment.

FIGS. 8A and 8B are diagrams explaining a method of manufacturing solar cell module 100 according to the first embodiment.

FIGS. 9A and 9B are diagrams explaining a method of manufacturing solar cell module 100 according to the first embodiment.

FIG. 10 is a plan view illustrating solar cell 10 according to a second embodiment and seen from the back-surface side.

FIG. 11 is an enlarged sectional view taken along B-B line of FIG. 10.

FIGS. 12A and 12B are diagrams explaining a method of manufacturing solar cell module 100 according to the second embodiment.

FIGS. 13A and 13B are diagrams explaining a method of manufacturing solar cell module 100 according to the second embodiment.

FIGS. 14A and 14B are diagrams explaining a method of manufacturing solar cell module 100 according to the second embodiment.

FIG. 15 is a diagram illustrating results of measuring the current-output distribution of solar cell 10 according to the second embodiment.

### DETAILED DESCRIPTION OF EMBODIMENTS

Embodiments of the invention are explained with reference to the drawings. In the respective drawings referenced herein, the same constituents are designated by the same reference numerals and duplicate explanation concerning the same constituents is omitted. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

Prepositions, such as “on”, “over” and “above” may be defined with respect to a surface, for example a layer surface, regardless of that surface's orientation in space. The preposition “above” may be used in the specification and claims even if a layer is in contact with another layer. The preposition “on” may be used in the specification and claims when a layer is not in contact with another layer, for example, when there is an intervening layer between them.

[First Embodiment]

(General Configuration of the Solar Cell Module)

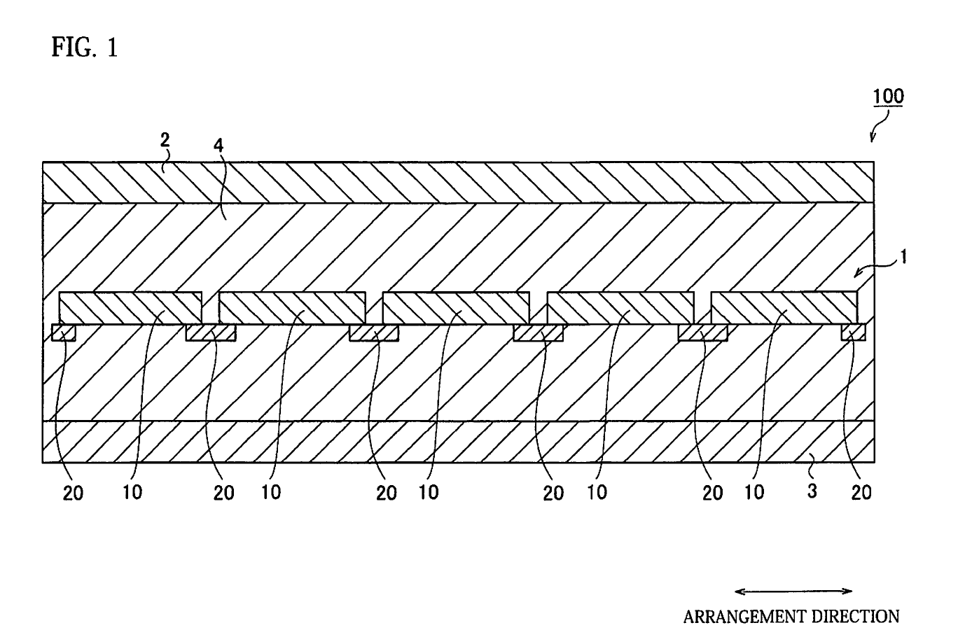

The general configuration of solar cell module 100 according to a first embodiment is described below by referring to FIG. 1. FIG. 1 is a side view illustrating solar cell module 100 according to the first embodiment.

As FIG. 1 shows, solar cell module 100 includes solar cell string 1, light-receiving-surface-side protection material 2, back-surface-side protection material 3, and sealing material 4. Solar cell module 100 is formed by sealing, with sealing material 4, solar cell string 1 between light-receiving-surface-side protection material 2 and back-surface-side protection material 3.

Solar cell string 1 is sealed with sealing material 4 between light-receiving-surface-side protection material 2 and back-surface-side protection material 3. Solar cell string 1 includes plural solar cells 10 and wiring materials 20. The configuration of solar cell string 1 is described in detail later.

Plural solar cells 10 are arranged in an arrangement direction shown in FIG. 1 . Each of plural solar cells 10 includes therein an n-type semiconductor region and a p-type semiconductor region. A semiconductor junction is formed between the n-type semiconductor region and the p-type semiconductor region. Each solar cell 10 receives light through its principal surface and thus generates photogenerated carriers (i.e., pairs of a hole and an electron). In a first embodiment, each solar cell 10 is a so-called back junction solar cell that has electrodes formed on its back surface. The configuration of each solar cell 10 is described in detail later.

Wiring materials 20 are used to electrically connect plural solar cells 10 to one another. Specifically, each wiring material 20 connects an electrode of a first solar cell 10 to an electrode of a second solar cell 10 that is adjacent to the first solar cell 10. It is preferable that each wiring material 20 is made of any material having low electrical resistivity, which is in either a thin-plate shape or a stranded-wire shape. Examples of the preferable materials are copper, silver, gold, zinc, nickel, aluminum, alloys of these metals, and the like. Note that the surfaces of each wiring material 20 may be coated with a conductive material, such as lead-free solder (e.g., SnAg_{3.0}Cu_{0.5}).

Light-receiving-side protection material 2 is located at the light-receiving-surface sides of plural solar cells 10 and thus protects the surface of solar cell module 100. Some of the materials possibly used for light-receiving-surface-side protection material 2 are optically-transparent but water-impermeable glass and optically-transparent plastics.

Back-surface-side protection material 3 is located at the back-surface sides of plural solar cells 10, and protects the back surface of solar cell module 100. Some of the materials possibly used for back-surface-side protection material 3 are resin films such as one made of PET (polyethylene terephthalate), laminate films such as one having a structure in which an Al foil is sandwiched by resin films. Sealing material 4 seals solar cell string 1 disposed between light-receiving-surface-side protection material 2 and back-surface-side protection material 3. Some of the materials possibly used for sealing material 4 are optically-transparent resins such as EVA, EEA, PVB, silicone, urethane, acryl, and epoxy. Note that an Al frame or the like maybe fitted to the outer edges of solar cell module 100 having the above-described configuration.

(Configuration of Solar Cell)

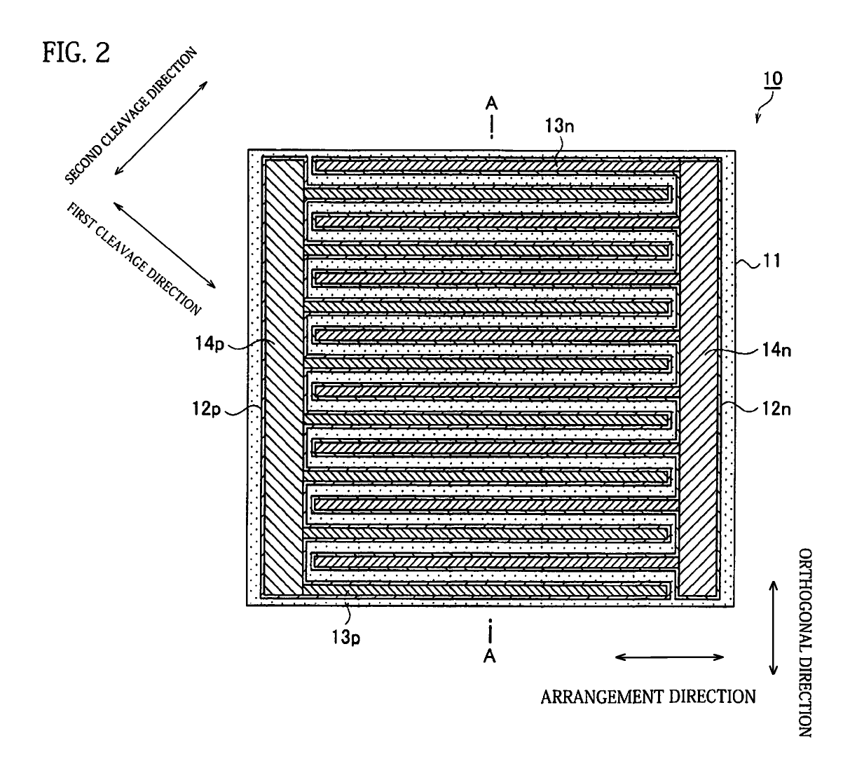

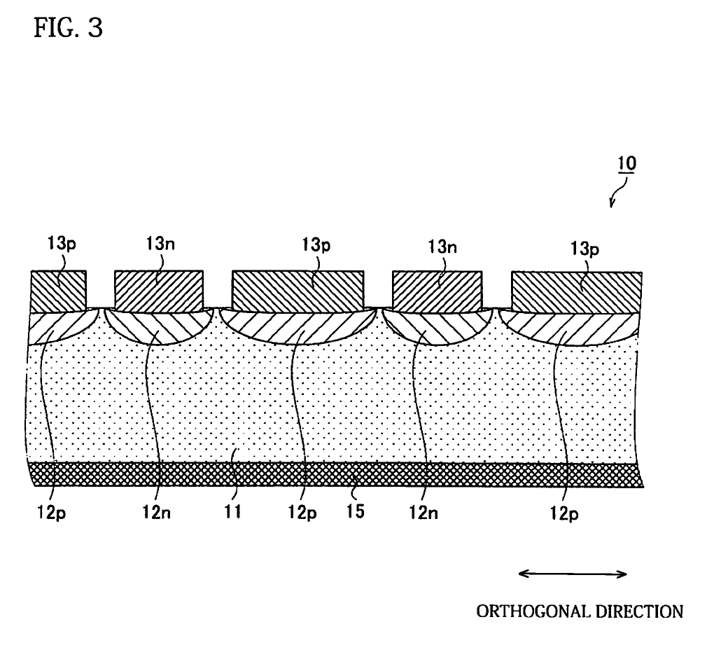

Next, the configuration of the solar cell according to the first embodiment is described by referring to the drawings. FIG. 2 is a plan view illustrating solar cell 10 according to the first embodiment and seen from the back-surface side. FIG. 3 is an enlarged sectional view taken along the A-A line of FIG. 2.

As FIGS. 2 and 3 show, solar cell 10 includes semiconductor substrate 11 of either p-type or n-type, n-type semiconductor region 12n, p-type semiconductor region 12p, plural n-side fine-wire electrodes 13n, plural p-side fine-wire electrodes 13p, n-side connection electrode 14n, p-side connection electrode 14p, and passivation layer 15. The following description is based on a case where n-type semiconductor substrate 11 is used.

Semiconductor substrate 11 has a surface to receive incident light, referred to as a “light-receiving surface”, and a surface located at the opposite side from the light-receiving surface, referred to as a “back surface.” Semiconductor substrate 11 according to the first embodiment is formed of a semiconductor material doped with an n-type dopant. Commonly-available semiconductor materials including crystalline semiconductor materials, such as monocrystalline silicon, and compound semiconductor materials, such as GaAs and InP can be used for such a semiconductor. Note that semiconductor substrate 11 of the first embodiment has cleavage planes located inside. Of the two kinds of photogenerated carriers generated in semiconductor substrate 11, the electrons are the majority carriers and the holes are the minority carriers.

N-type semiconductor region 12n is a high-concentration n-type diffusion region formed by doping an n-type dopant (e.g., phosphorus with respect to Si substrate) into the back surface of semiconductor substrate 11. N-type semiconductor region 12n has a higher concentration of the n-type dopant than the other portion of semiconductor substrate 11. Among the two kinds of photogenerated carriers, the electrons are concentrated in n-type semiconductor region 12n. As FIG. 2 shows, in the first embodiment, each of plural comb-tooth-like portions of n-type semiconductor region 12n is formed to extend in the arrangement direction. In addition, the comb-tooth-like portions of n-type semiconductor region 12n are arranged substantially parallel with each other in the orthogonal direction which is a direction orthogonal to the arrangement direction.

P-type semiconductor region 12p is a high-concentration p-type diffusion region formed by doping a p-type dopant (e.g., boron or aluminum with respect to a Si substrate) into the back surface of semiconductor substrate 11. P-type semiconductor region 12p has a higher concentration of the p-type dopant than the other portion of semiconductor substrate 11. Among the two kinds of photogenerated carriers, the holes are concentrated in p-type semiconductor region 12p. As FIG. 2 shows, in the first embodiment, each of plural comb-tooth-like portions of p-type semiconductor region 12p is formed to extend in the arrangement direction. In addition, the comb-tooth-like portions of p-type semiconductor region 12p are arranged substantially parallel with each other in the orthogonal direction.

Note that n-type semiconductor region 12n and p-type semiconductor region 12p of the first embodiment are formed such that their respective dopants are doped into semiconductor substrate 11 by laser radiation. Detailed description of the doping process is given later.

Plural n-side fine-wire electrodes 13n are collector electrodes to collect carriers from n-type semiconductor region 12n. Plural n-side fine-wire electrodes 13n are formed respectively on the comb-tooth-shaped portions of n-type semiconductor region 12n. Accordingly, each n-side fine-wire electrode 13n is formed so as to extend in the arrangement direction. Each n-side fine-wire electrode 13n may have either a single layer or plural layers, and may be made of a low-resistivity material. For example, each n-side fine-wire electrode 13n may include a contact layer and a low-resistivity layer. The contact layer is formed on n-type semiconductor region 12n and is made of Al, transparent conductive oxides (TCO), or the like. The low-resistivity layer is formed on the contact layer and is made of Ag, Cu, or the like. Note that if the low-resistivity layer is formed by plating, the thermal stress that remains inside of the low-resistivity layer can be kept low. So, the use of plating can make distortion of semiconductor substrate 11 less likely to occur.

Plural p-side fine-wire electrodes 13p are collector electrodes to collect carriers from p-type semiconductor region 12p. Plural p-side fine-wire electrodes 13p are formed respectively on the comb-tooth-shaped portions of p-type semiconductor region 12p. Accordingly, each p-side fine-wire electrode 13p is formed so as to extend in the arrangement direction. Each p-side fine-wire electrode 13p can be formed in a similar manner to the above-described formation of n-side fine-wire electrodes 13n.

N-side connection electrode 14n is an electrode to which wiring materials 20 are connected. As FIG. 2 shows, n-side connection electrode 14n is formed on n-type semiconductor region 12n so as to extend in the orthogonal direction. N-side connection electrode 14n is connected to plural n-side fine-wire electrodes 13n. Note that n-side connection electrode 14n may function as an electrode to collect carriers from n-type semiconductor region 12n.

P-side connection electrode 14p is an electrode to which wiring materials 20 are connected. As FIG. 2 shows, p-side connection electrode 14p is formed on p-type semiconductor region 12p so as to extend in the orthogonal direction. P-side connection electrode 14p is connected to plural p-side fine-wire electrodes 13p. Note that p-side connection electrode 14p may function as an electrode to collect carriers from p-type semiconductor region 12p.

Though not illustrated, both n-side connection electrode 14n and p-side connection electrode 14p can be formed in a similar manner to the above-described formation of n-side fine-wire electrodes 13n.

As FIG. 3 shows, passivation layer 15 covers substantially the entire area of the light-receiving surface of semiconductor substrate 11. Passivation layer 15 functions to prevent carrier recombination. For example, passivation layer 15 is an amorphous semiconductor layer that is formed either without doping or by doping only a small amount of dopant.

(Cleavage Plane of the Semiconductor Substrate)

Next, cleavage planes of semiconductor substrate 11 according to the first embodiment are described by referring to FIG. 2.

Semiconductor substrate 11 of the first embodiment has two cleavage planes. Such semiconductor substrate 11 is more likely to split in the two directions that are parallel respectively to the two cleavage planes (the two directions are referred to as “first cleavage direction” and “second cleavage direction” in FIG. 2). Each cleavage direction is orthogonal to the crystal orientation of the corresponding cleavage plane.

For example, if semiconductor substrate 11 is a monocrystalline silicon substrate that has the (100) plane as its back surface, semiconductor substrate 11 has two cleavage planes (specifically, the (110) plane and the (1-10) plane) that are orthogonal to each other. Alternatively, if semiconductor substrate 11 is a GaAs substrate that has the (001) plane as its back surface, semiconductor substrate 11 has two cleavage planes (specifically, the (110) plane and the (1-10) plane) that are orthogonal to each other.

As described above, the comb-tooth-like portions of n-type semiconductor region 12n and the comb-tooth-like portions of p-type semiconductor region 12p are formed so as to extend in the arrangement direction shown in FIG. 2. The arrangement direction is a direction that intersects both the first cleavage direction and the second cleavage direction. In other words, the arrangement direction is a direction that intersects both of the cleavage planes of semiconductor substrate 11. Accordingly, the comb-tooth-like portions of n-type semiconductor region 12n and the comb-tooth-like portions of p-type semiconductor region 12p are formed so as to extend in a direction that intersects both of the cleavage planes of semiconductor substrate 11.

(Configuration of the Solar Cell String)

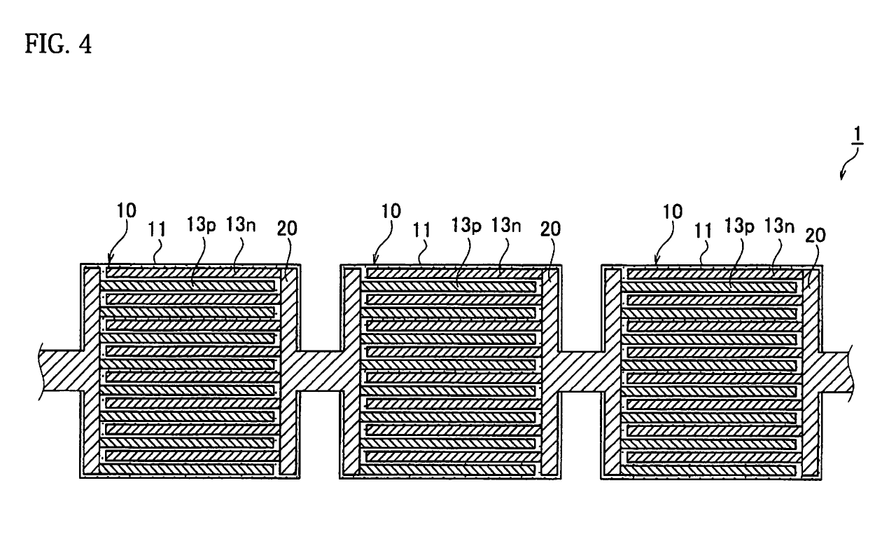

Next, the configuration of solar cell string 1 according to the first embodiment is described by referring to the drawings. FIG. 4 is an enlarged plan view illustrating solar cell string 1 according to the first embodiment and seen from the back-surface side.

As FIG. 4 shows, plural solar cells 10 are connected to one another by means of wiring materials 20. Specifically, a first end portion of any one of wiring material 20 is electrically connected to n-side connection electrode 14n of one of solar cells 10. The other end of the same wiring material 20 is electrically connected to p-side connection electrode 14p of another one of solar cells 10. Each wiring material 20 is connected to n-side connection electrode 14n and p-side connection electrode 14p by use of conductive adhesives, such as solders and conductive-resin adhesives.

(Method of Manufacturing the Solar Cell)

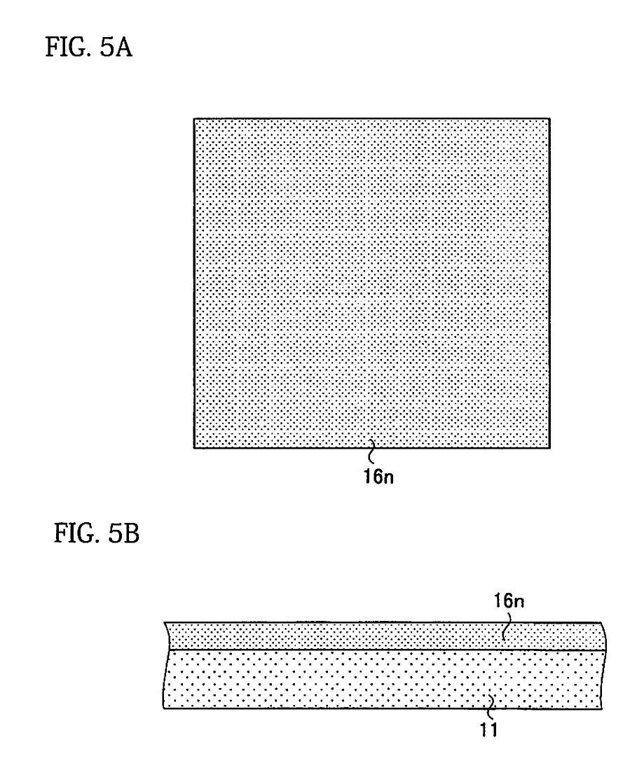

Next, a method of manufacturing solar cell module 100 according to the first embodiment is described by referring to FIGS. 5A and 5B to FIGS. 9A and 9B. Note that each of FIGS. 5A, 6A, 7A, 8A, and 9A is a plan view illustrating semiconductor substrate 11 and seen from the back-surface side. FIGS. 5B, 6B, 7B, 8B, and 9B are enlarged sectional views taken in the orthogonal directions of their respective FIGS. 5A, 6A, 7A, 8A, and 9A.

First, semiconductor substrate 11 is washed by either an acidic or an alkaline solution. Then, a microscopic texture is formed on the light-receiving surface of semiconductor substrate 11 by etching.

Next, as FIGS. 5A and 5B show, n-type coating layer 16n is formed to cover substantially the entire back surface of semiconductor substrate 11. The back surface is either coated with a diffusing agent containing an n-type dopant or dipped in the diffusing agent.

Next, n-type coating layer 16n is heated at a predetermined temperature (e.g. 100° C. to 200° C., approximately) for a predetermined time (e.g., for 2 minutes, approximately). Thus, n-type coat layer 16n is solidified.

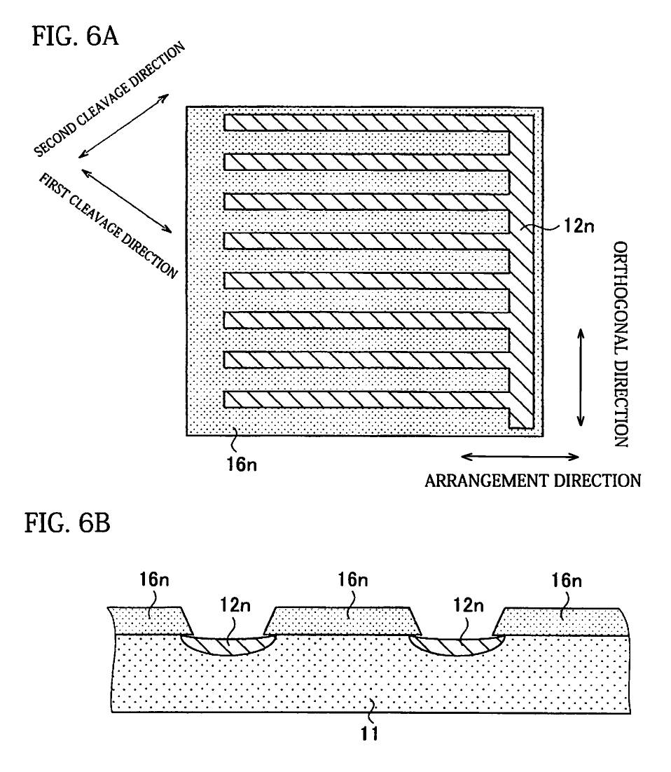

Then, n-type coating layer 16n is irradiated with laser light (e.g. third harmonic of YAG laser) so as to form comb-tooth-like portions of n-type semiconductor region 12n shown in FIGS. 6A and 6B. In this case, the laser light must be directed in a direction that intersects both of the cleavage planes of semiconductor substrate 11. Accordingly, the comb-tooth-like portions of n-type semiconductor region 12n are formed so as to extend in the direction that intersects both of the cleavage planes of semiconductor substrate 11. Note that scanning with the laser light can be performed by use of a galvanometer mirror, an XY stage, or the like.

In addition, by directing laser light onto n-type coating layer 16n in the orthogonal direction, the comb-tooth-like portions of n-type semiconductor region 12n are connected together. In the first embodiment, the orthogonal direction is a direction that intersects both of the cleavage planes of semiconductor substance 11 as the arrangement direction does.

Next, n-type coating layer 16n is removed using a solution of HF or the like.

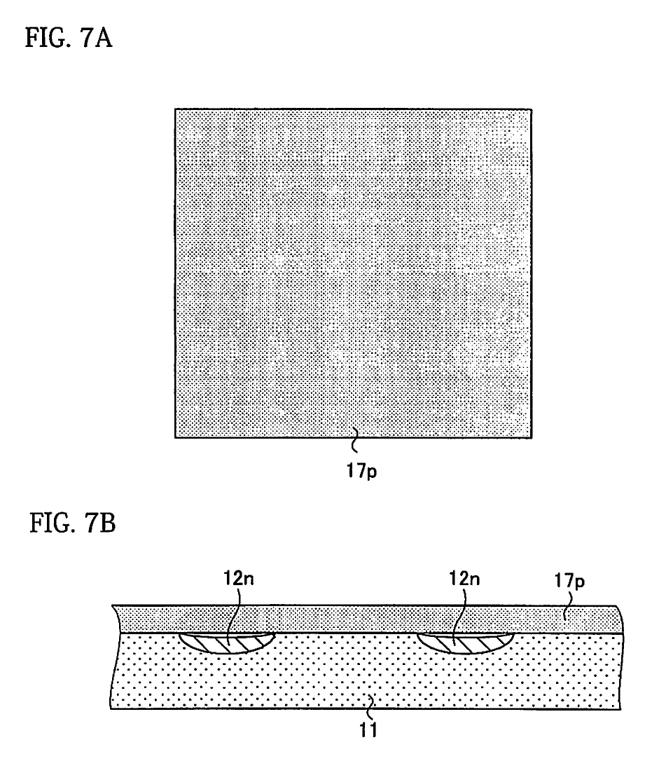

Next, as FIGS. 7A and 7B show, p-type coating layer 17p is formed to cover substantially the entire back surface of semiconductor substrate 11. The back surface is either coated with a diffusing agent containing a p-type dopant or dipped in the diffusing agent.

Next, p-type coating layer 17p is heated at a predetermined temperature (e.g. 100° C. to 200° C., approximately) for a predetermined time (e.g., for 2 minutes, approximately). Thus, p-type coating layer 17p is solidified. Then, under an oxygen atmosphere, p-type coating layer 17p is subjected to an asking process (to remove carbon) at a predetermined temperature (e.g., 600° C.). This process can promote the diffusion of the p-type dopant executed by the following process.

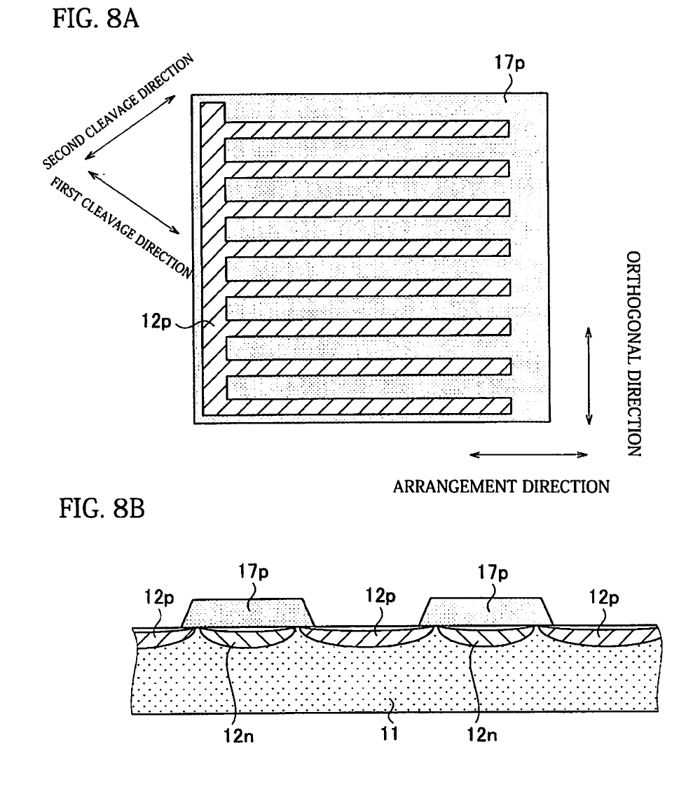

Next, p-type coating layer 17p is irradiated with laser light (e.g. third harmonic of YAG laser) so as to form comb-tooth-like portions of p-type semiconductor region 12p shown in FIGS. 8A and 8B. In this case, the laser light must be directed in a direction that intersects both of the cleavage planes of semiconductor substrate 11. Accordingly, the comb-tooth-like portions of p-type semiconductor region 12p are formed so as to extend in the direction that intersects both of the cleavage planes of semiconductor substrate 11. Note that scanning with the laser light can be performed by use of a galvanometer mirror, an XY stage, or the like.

In addition, by directing laser light onto p-type coating layer 17p in the orthogonal direction, the comb-tooth-like portions of p-type semiconductor region 12p are connected together.

Next, p-type coat layer 17p is removed using a solution of HF or the like.

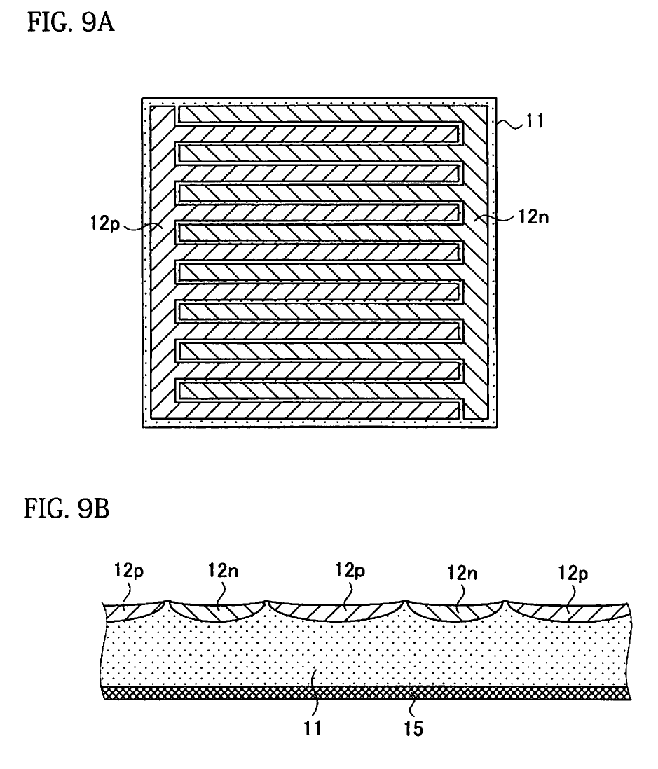

Next, as FIGS. 9A and 9B show, passivation layer 15 is formed on the light-receiving surface of semiconductor substrate 11. Next, a contact layer (e.g., an ITO layer) is formed on both n-type semiconductor region 12n and p-type semiconductor region 12p, and then a low-resistivity layer (e.g., an Ag layer, which is formed by sputtering) is formed on the contact layer. Thus formed are n-side electrodes (specifically, plural n-side fine-wire electrodes 13n and n-side connection electrode 14n) and p-side electrodes (plural p-side fine-wire electrodes 13p and p-side connection electrode 14p). Thus, solar cells 10 are completed.

Next, plural solar cells 10 are arranged in the arrangement direction, and plural solar cells 10 thus arranged are connected to one another by wiring materials 20. Specifically, a first end portion of each wiring material 20 is connected to n-side connection electrode 14n of one of solar cells 10, and the other end of the same wiring material 20 is connected to p-side connection electrode 14p of another solar cell 10. Thus, solar cell string 1 is completed.

Next, sealing material 4, solar cell string, another sealing material 4, back-surface-side protection material 3 are disposed on one upon another in this order on light-receiving-surface-side protection material 2.

Next, a laminating process is executed to form an integrated body of the above-mentioned components that are placed one upon another.

(Advantageous Effects)

N-type semiconductor region 12n of each solar cell 10 according to the first embodiment is a region formed by doping semiconductor substrate 11 with n-type dopant by laser radiation. N-type semiconductor region 12n is formed so as to extend in a direction that intersects the cleavage planes of semiconductor substrate 11.

Accordingly, the temperature change caused by the laser radiation cannot generate distortion inside semiconductor substrate 11 along the cleavage planes. Consequently, when n-type semiconductor region 12n is formed, cracks along the cleavage planes are prevented from being formed in semiconductor substrate 11.

Likewise, p-type semiconductor region 12p is a region formed by doping semiconductor substrate 11 with a p-type dopant by laser radiation. P-type semiconductor region 12p is formed so as to extend in a direction that intersects the cleavage planes of semiconductor substrate 11.

Accordingly, the temperature change caused by the laser radiation cannot generate distortion inside of semiconductor substrate 11 along the cleavage planes. Consequently, when p-type semiconductor region 12p is formed, cracks along the cleavage planes are prevented from being formed in semiconductor substrate 11.

According to the above-mentioned embodiment, deterioration of characteristics of solar cell 10 is prevented, as well as the manufacturing productivity is improved.

[Second Embodiment]

A second embodiment of the invention is described below by referring to the drawings. The following description focuses mainly on the differences between the first and the second embodiments. Specifically, p-type semiconductor region 12p of the second embodiment is formed by methods other than laser radiation. In addition, semiconductor substrate 11 of the second embodiment is n-type. Specifically, in the second embodiment, a semiconductor region having the opposite conductivity type to that of the semiconductor substrate 11 is formed by methods other than laser radiation. An example of such methods is the chemical vapor deposition (CVD) method. The following description is based on a case where the CVD method is employed as an example method of forming a p-type amorphous semiconductor region.

(Configuration of the Solar Cell)

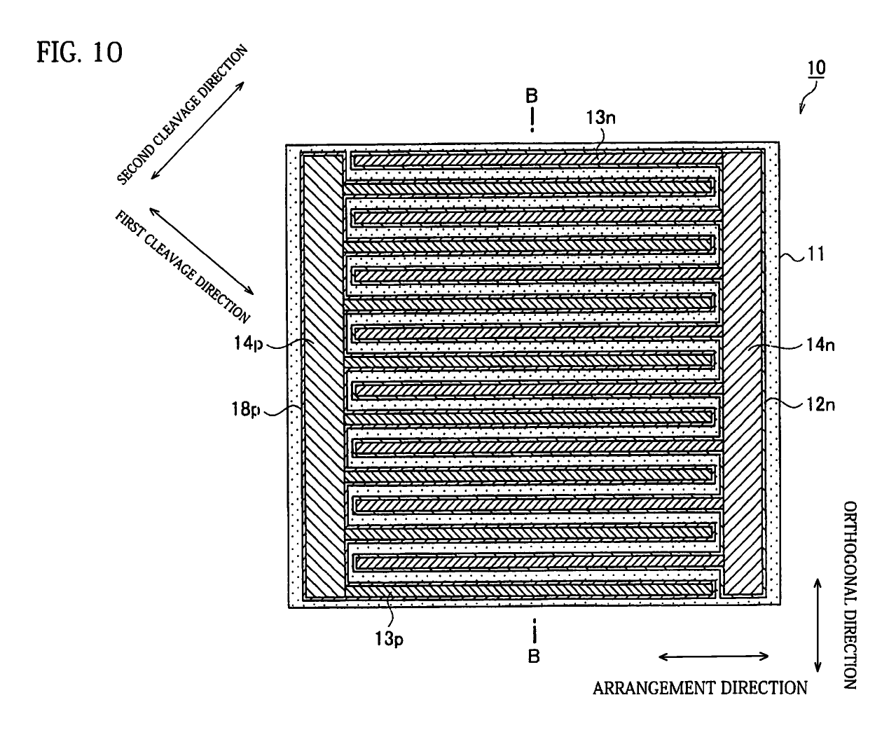

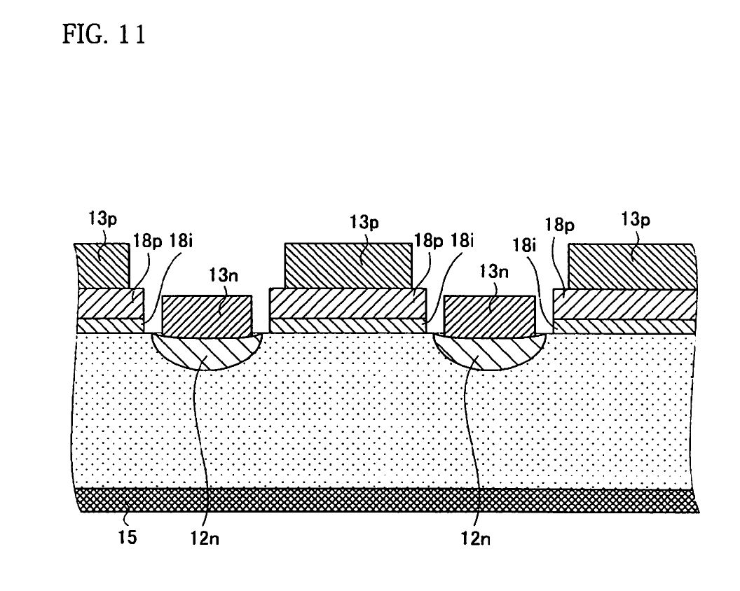

The configuration of solar cell 10 according to the second embodiment is described below by referring to the drawings. FIG. 10 is a plan view illustrating solar cell 10 according to the second embodiment and seen from the back-surface side. FIG. 11 is an enlarged sectional view taken along the B-B line of FIG. 10.

As FIGS. 10 and 11 show, solar cell 10 includes p-type amorphous semiconductor region 18p and i-type amorphous semiconductor region 18i.

P-type amorphous semiconductor region 18p is a region which is formed by the CVD method and layered on the back surface of semiconductor substrate 11. As FIG. 10 shows, each of comb-tooth-like portions of p-type amorphous semiconductor region 18p is formed to extend in the arrangement direction. In addition, the comb-tooth-like portions of p-type amorphous semiconductor region 18p are arranged substantially parallel with each other in the orthogonal direction. Plural p-side fine-wire electrodes 13p and p-side connection electrodes 14p are formed on p-type amorphous semiconductor region 18p.

I-type amorphous semiconductor region 18i is interposed between semiconductor substrate 11 and p-type amorphous semiconductor region 18p. The thickness of i-type amorphous semiconductor region 18i is, for example, approximately 5 nm. This structure, that is, a structure having i-type amorphous semiconductor region 18i interposed between semiconductor substrate 11 and p-type amorphous semiconductor region 18p is known as the “HIT structure”. According to the HIT structure, pn junction characteristics are enhanced. The rest of the configuration of solar cell 10 is similar to that of the first embodiment.

(Method of Manufacturing the Solar Cell)

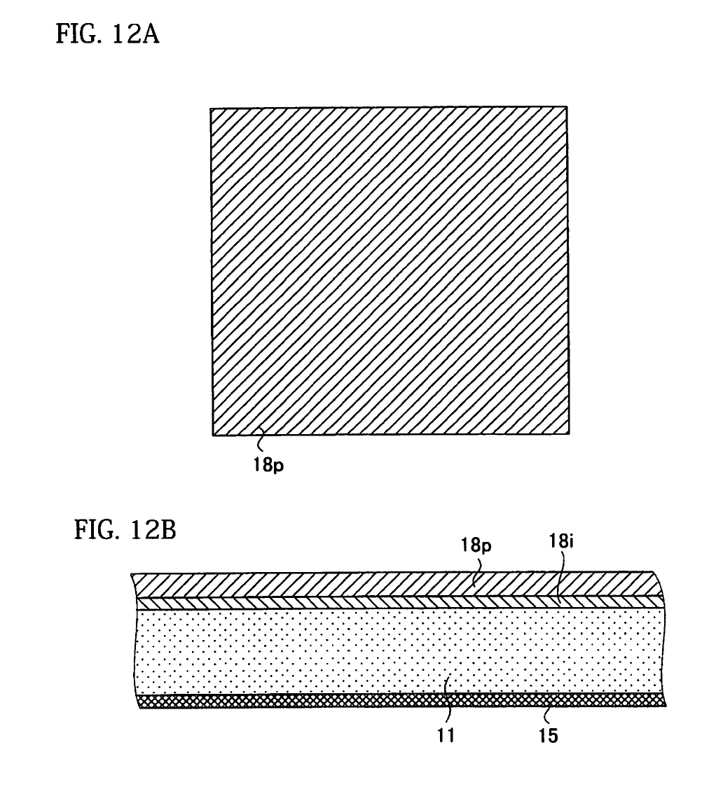

Next, a method of manufacturing solar cell 10 according to the second embodiment is described by referring to FIGS. 12A and 12B to FIGS. 14A and 14B. Note that each of FIGS. 12A, 13A, and 14A is a plan view illustrating semiconductor substrate 11 and seen from the back-surface side. FIGS. 12B, 13B, and 14B are enlarged sectional views taken in the orthogonal directions of their respective FIGS. 12A, 13A, and 14A.

First, semiconductor substrate 11 is washed by an acidic or alkaline solution. Then, a microscopic texture is formed on the light-receiving surface of semiconductor substrate 11 by etching.

Next, passivation layer 15 is formed on the light-receiving surface of semiconductor substrate 11.

Next, as FIGS. 12A and 12B show, i-type amorphous semiconductor region 18i is formed on the entire back surface of semiconductor substrate 11 by the CVD method. Then, p-type amorphous semiconductor region 18p is formed on i-type amorphous semiconductor region 18i by the CVD method.

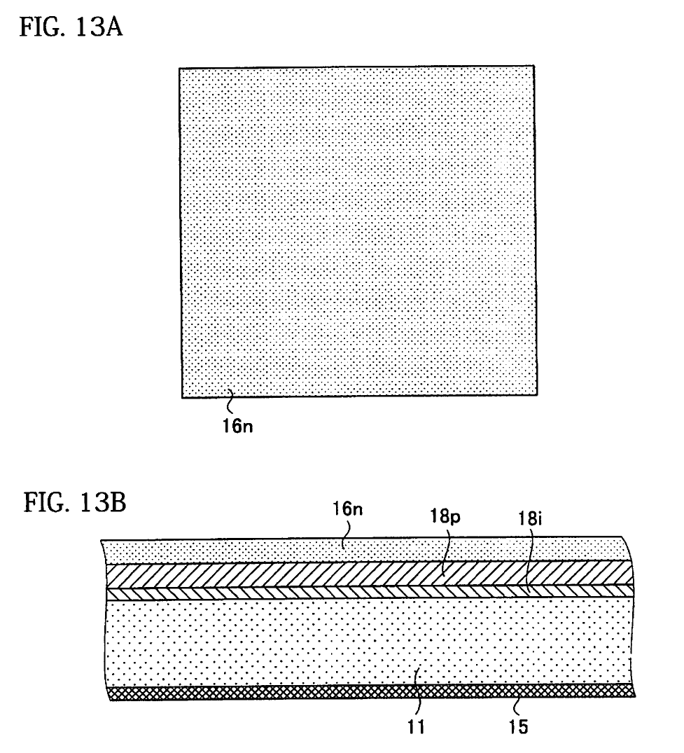

Next, as FIGS. 13A and 13B show, n-type coating layer 16n is formed to cover substantially the entire back surface of semiconductor substrate 11. The back surface is either coated with a diffusing agent containing an n-type dopant or dipped in the diffusing agent.

Next, n-type coating layer 16n is heated at a predetermined temperature (namely, the temperature which does not change the properties of i-type and p-type amorphous semiconductor layers 18i and 18p; specifically, the temperature is within, for example, a range from 100° C. to 200° C., approximately) for a predetermined time (e.g., for 2 minutes, approximately). Thus, n-type coat layer 16n is solidified.

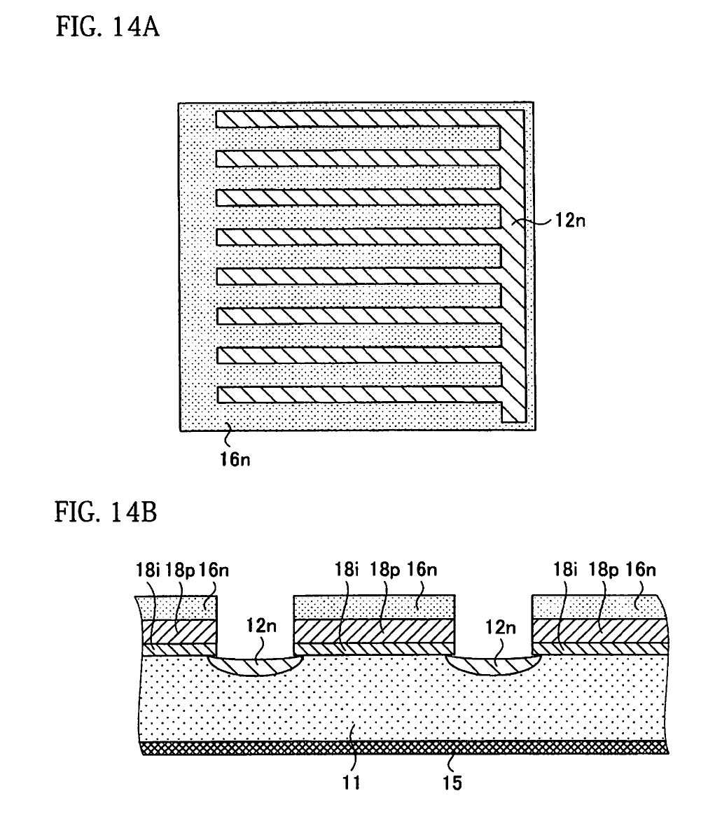

Then, n-type coat layer 16n is irradiated with laser light (e.g., third harmonic of YAG laser) so as to form comb-tooth-like portions of n-type semiconductor region 12n shown in FIGS. 14A and 14B. In this case, the laser light must be directed in a direction that intersects both of the cleavage planes of semiconductor substrate 11. Accordingly, the comb-tooth-like portions of n-type semiconductor region 12n are formed so as to extend in the direction that intersects both of the cleavage planes of semiconductor substrate 11. Note that scanning with the laser light can be executed by use of a galvanometer mirror, an XY stage, or the like. In addition, it is preferable to adjust the output of the laser apparatus, the amount of defocusing, the pulse width, the duty ratio, and the like so that i-type amorphous semiconductor region 18i and p-type amorphous semiconductor region 18p are not sublimated.

In addition, by directing laser light onto n-type coat layer 16n in the orthogonal direction, the comb-tooth-like portions of n-type semiconductor region 12n are connected together. In the second embodiment, the orthogonal direction is a direction that intersects both of the cleavage planes of semiconductor substance 11 as the arrangement direction does.

Next, n-type coating layer 16n is removed using a solution of HF or the like.

Next, a contact layer (e.g., an ITO layer) is formed on both n-type semiconductor region 12n and p-type amorphous semiconductor region 18p, and then a low-resistivity layer (e.g., an Ag layer, which is formed by sputtering) is formed on the contact layer. Thus formed are n-side electrodes (specifically, plural n-side fine-wire electrodes 13n and n-side connection electrode 14n) and p-side electrodes (plural p-side fine-wire electrodes 13p and p-side connection electrode 14p). Thus, solar cells 10 are completed.

(Advantageous Effects)

N-type semiconductor region 12n of each solar cell 10 according to the second embodiment is a region formed by doping semiconductor substrate 11 with a n-type dopant by laser radiation. N-type semiconductor region 12n is formed so as to extend in a direction that intersects the cleavage planes of semiconductor substrate 11.

Accordingly, the temperature change caused by laser radiation cannot generate distortion inside semiconductor substrate 11 along the cleavage planes. Consequently, when n-type semiconductor region 12n is formed, cracks along the cleavage planes are prevented from being formed in semiconductor substrate 11.

In addition, p-type amorphous semiconductor region 18p of solar cell 10 according to the second embodiment is formed by methods other than laser radiation, specifically, by the CVD method.

Accordingly, in comparison to the case where p-type amorphous semiconductor region 18p is doped with p-type dopant diffusing agent by laser radiation, the method employed in the second embodiment yields less thermal damages to semiconductor substrate 11. In addition, the method employed in the second embodiment prevents distortion from being generated inside semiconductor substrate 11. So, even if microscopic cracks are formed when n-type semiconductor region 12n is formed, such microscopic cracks cannot cause splitting of semiconductor substrate 11.

In addition, in solar cell 10 according to the second embodiment, n-type semiconductor region 12n, which has the same conductivity type as that of semiconductor substrate 11, is formed by doping by laser radiation. Accordingly, the semiconductor region to collect the majority carriers (i.e., electrons in the second embodiment) is formed by the laser doping method, whereas the semiconductor region to collect the minority carriers (i.e., holes in the second embodiment) is formed by the CVD method. The CVD method yields less thermal damage to semiconductor substrate 11 than the laser doping method does when their respective semiconductor regions are formed. Accordingly, thermal damage to semiconductor substrate 11 is low when the semiconductor region to collect the minority carriers is formed, so the efficiency of minority-carrier collection is improved.

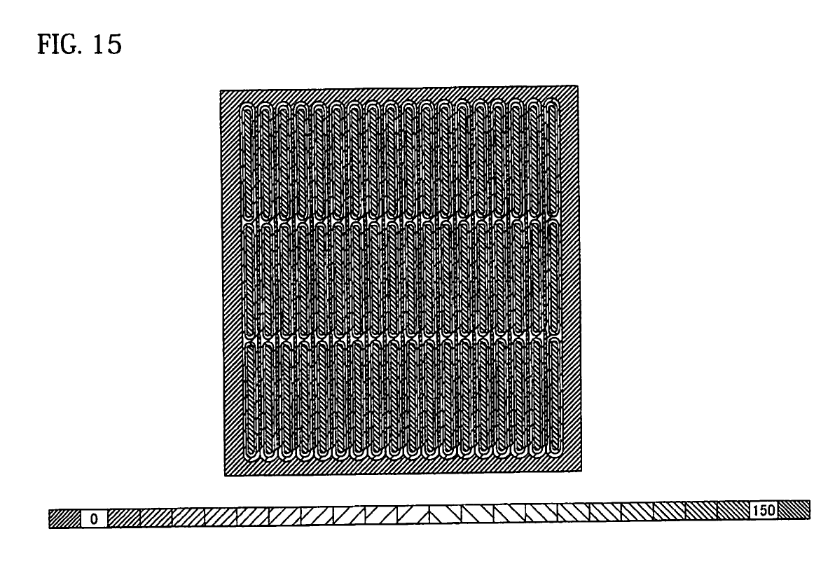

FIG. 15 shows the results of measuring the current-output distribution of a case where solar cell 10 according to the second embodiment is irradiated with laser light by the laser beam induced current (LBIC) method. The results show that sufficient current output is observed both in n-type semiconductor region 12n and in p-type amorphous semiconductor region 18p. Compared with the results for the first embodiment, the results for the second embodiment show that the current output for p-type amorphous semiconductor region 18p is quite sufficient.

(Other Embodiments)

The invention has been described thus far by above embodiments. However, the descriptions and the drawings that constitute parts of this disclosure should not be understood as limitations to the invention. Those skilled in the art may conceive of various alternative embodiments, examples, and application techniques from the disclosure.

For example, in the embodiments described above, the diffusing agent containing the dopant is applied substantially to the entire back surface of semiconductor substrate 11. This is not the only way of applying the diffusing agent. For example, the diffusing agent containing the dopant may be applied only to the region where the semiconductor region is to be formed. In this way, steps of manufacturing solar cell 10 can be reduced as well as manufacturing costs can be lowered.

The description of the second embodiment is based on a case where the CVD method is employed as an example method of forming the semiconductor region. The CVD method is not the only method that is possible for this purpose. For example, the semiconductor region may be formed by the thermal diffusion method. In this case, the diffusion coefficient of the dopant used in the formation of the semiconductor region by the laser doping method is preferably larger than the diffusion coefficient of the dopant used in the formation of the semiconductor region by the thermal diffusion method. With this diffusion coefficient, the laser radiation is executed for a shorter time, so that thermal damage to semiconductor substrate 11 can be reduced further.

In addition, in the above-described embodiments, n-type semiconductor region 12n and p-type semiconductor region 12p are formed so as to extend in the arrangement direction. This is not the only way of forming n-type semiconductor region 12n and p-type semiconductor region 12p. N-type semiconductor region 12n and p-type semiconductor region 12p only have to be formed to extend in a direction intersecting the cleavage planes of semiconductor substrate 11.

In addition, each solar cell 10 of the above-described embodiments includes passivation layer 15 located on the light-receiving-surface side of semiconductor substrate 11. This is not the only possible configuration of solar cell 10. Instead of passivation layer 15, each solar cell 10 may include a semiconductor layer having the same conductivity type as that of semiconductor substrate 11. This semiconductor layer serves as the front surface field (FSF) to reflect the hole carriers off the light-receiving surface of semiconductor substrate 11. In addition, solar cell 10 does not have to include passivation layer 15.

In addition, each solar cell 10 of the above-described embodiments includes n-type semiconductor substrate 11. Alternatively, solar cell 10 may include p-type semiconductor substrate 11. In this case, the n-type semiconductor region is formed by methods other than laser radiation in the second embodiment, by the CVD method, for example. In addition, a texture is formed on the light-receiving surface of semiconductor substrate 11 of the above-described embodiments, but the texture does not have to be formed.

In addition, the laser doping method employed in the above-described embodiments is executed using the third harmonic of YAG laser. This is not the only usable laser light. For example, the fundamental YAG laser (1064 nm), the second harmonic (532 nm), XeC1 excimer laser (308 nm), KrF excimer laser (248 nm), ArF excimer laser (198 nm), or the like may be used for this purpose.

In addition each of the electrodes of the above-described embodiments includes a contact layer and a low-resistivity layer. This is not the only possible configuration of the electrode. For example, each electrode maybe formed by sputtering Ag, or by printing/applying a conductive paste. Printing of or applying of the conductive paste can be executed by various methods, such as the screen-printing method. The inkjet method and dispenser method are some of the other methods possible for this purpose.

As described above, cracks are prevented from being formed in the semiconductor substrate in a solar cell according to the embodiments.

The invention includes other embodiments in addition to the above-described embodiments without departing from the spirit of the invention. The embodiments are to be considered in all respects as illustrative, and not restrictive. The scope of the invention is indicated by the appended claims rather than by the foregoing description. Hence, all configurations including the meaning and range within equivalent arrangements of the claims are intended to be embraced in the invention.

What is claimed is:

1. A solar cell comprising:
a semiconductor substrate including a light-receiving surface and a back surface that is disposed at the opposite side from the light-receiving surface;
a first conductivity type semiconductor region having a first conductivity type and formed on the back surface, the first conductivity type semiconductor region is a region that a first dopant is doped into the semiconductor substrate by laser radiation, wherein the first conductivity type semiconductor region is a region formed to extend in a direction that intersects cleavage planes of the semiconductor substrate; and
a second conductivity type semiconductor region having a second conductivity type that is different from the first conductivity type and formed on the back surface.

2. The solar cell according to claim 1,
wherein the semiconductor substrate has two cleavage planes,
wherein the first conductivity type semiconductor region is a region formed to extend in a direction that intersects each of the two cleavage planes of the semiconductor substrate.

3. The solar cell according to claim 1,
wherein the second conductivity type semiconductor region is a region that a second dopant is doped into the semiconductor substrate by laser radiation, and
wherein the second conductivity type semiconductor region is a region formed to extend in a direction that intersect cleavage plane of the semiconductor substrate.

4. The solar cell according to claim 1,
wherein the semiconductor substrate has two cleavage planes,
wherein the second conductivity type semiconductor region is a region formed to extend in a direction that intersects each of the two cleavage planes of the semiconductor substrate.

5. The solar cell according to claim 1,
wherein the second conductivity type semiconductor region is an amorphous semiconductor layer formed on the back surface by a chemical vapor deposition (CVD) method.

6. The solar cell according to claim 1,
wherein the second conductivity type semiconductor region is a region formed on the back surface by doping a second dopant on the semiconductor substrate by a thermal diffusion method.

7. The solar cell according to claim 6,
wherein the first dopant's diffusion coefficient is larger than the second dopant's diffusion coefficient.

8. The solar cell according to claim 1,
wherein the semiconductor substrate has the first conductivity type.

9. A method of manufacturing a solar cell, comprising steps of:
forming, on a semiconductor substrate including a light-receiving surface and a back surface that is disposed at the opposite side from the light-receiving surface, a first conductivity type semiconductor region on the back surface and having a first conductivity type; and
forming a second conductivity type semiconductor region on the back surface and having a second conductivity type that is different from the first conductivity type,
wherein the first conductivity type semiconductor region is formed by doping a first dopant into the semiconductor substrate by laser radiation directed in a direction that intersects a cleavage plane of the semiconductor substrate.

10. The method of manufacturing a solar cell according to claim 9
wherein the second conductivity type semiconductor region on the back surface is formed by a CVD method.

11. The method of manufacturing a solar cell according to claim 9,
wherein the second conductivity type semiconductor region is formed by doping a second dopant into the semiconductor substrate by a thermal diffusion method.

12. A solar cell module comprising:
a plurality of solar cells, the solar cells comprising:
a semiconductor substrate including a light-receiving surface and a back surface that is disposed at the opposite side from the light-receiving surface;
a first conductivity type semiconductor region having a first conductivity type and formed on the back surface, the first conductivity type semiconductor region is a region that a first dopant is doped into the semiconductor substrate by laser radiation, wherein the first conductivity type semiconductor region is a region formed to extend in a direction that intersects cleavage planes of the semiconductor substrate; and
a second conductivity type semiconductor region having a second conductivity type that is different from the first conductivity type and formed on the back surface;
a wiring material that electrically connects each of the plurality of solar cells;
a light-receiving-surface-side protection material disposed on a light-receiving-surface side of each solar cell;
a back-surface-side protection material disposed on a back-surface side of each solar cell; and
a sealing material that seals the solar cell and the wiring material and disposed between the light-receiving-surface-side protection material and back-surface-side protection material.
